(19) United States
(12) Patent Application Publication
(10) Pub. No.: US 2024/0353634 A1
(43) Pub. Date: Oct. 24, 2024

(54) MANAGING RELATIVE THERMAL DRIFT OF CARRIER-MOUNTED INTEGRATED CIRCUITS

(71) Applicant: Ciena Corporation, Hanover, MD (US)

(72) Inventors: Raphael Beaupré-Laflamme, Quebec (CA); Claude Gamache, Gatineau (CA); François Pelletier, Quebec (CA); Georges Turcotte, Ottawa (CA)

(73) Assignee: Ciena Corporation, Hanover, MD (US)

(21) Appl. No.: 18/304,094

(22) Filed: Apr. 20, 2023

(51) Int. Cl. G02B 6/42; H10N 10/17

(52) U.S. Cl. CPC G02B 6/4271; G02B 6/428; H10N 10/17

(57) ABSTRACT

A circuit interconnection structure has a cavity formed through an entire thickness between first and second surfaces. A first integrated circuit is mounted on the first surface. A device carrier comprises a first portion that fits within at least a portion of the cavity. A second portion of the device carrier rigidly connected to the first portion of the device carrier is attached to the first surface. A device positioned within the first portion of the device carrier and mounted to a mounting surface of the device carrier is substantially parallel to the first surface. The device comprises a second integrated circuit. A total thermal expansion of the device carrier between the second portion of the device carrier and the mounting surface is substantially equal to a total thermal expansion of the device between the second integrated circuit and the portion of the device mounted to the mounting surface.

### TECHNICAL FIELD

This disclosure relates to managing relative thermal drift of carrier-mounted integrated circuits.

### BACKGROUND

Optically coupling the output of one photonic chip to the input of another photonic chip can allow for a broad range of applications. For example, a first photonic chip that generates light can be optically coupled to a second photonic chip that further manipulates the light, ultimately converting the light into electrical signals that are then transmitted to a printed circuit board (PCB). Maintaining the relative alignment between different photonic chips, or between other kinds of integrated circuit chips, can be challenging when different materials expand or contract due to thermal expansion.

### SUMMARY

In one aspect, in general, an apparatus comprises: a circuit interconnection structure comprising a first surface and a second surface, with a cavity formed through an entire thickness between the first surface and the second surface; a first integrated circuit comprising a first port, the first integrated circuit mounted on the first surface of the circuit interconnection structure; a device carrier comprising a first portion of the device carrier that fits within at least a portion of the cavity, wherein a second portion of the device carrier rigidly connected to the first portion of the device carrier is attached to the first surface of the circuit interconnection structure; and a device positioned within the first portion of the device carrier and mounted to a mounting surface of the device carrier that is substantially parallel to the first surface of the circuit interconnection structure, the device comprising a second integrated circuit comprising a second port. A total thermal expansion of the device carrier between the second portion of the device carrier and the mounting surface of the device carrier is substantially equal to a total thermal expansion of the device between the second integrated circuit and the portion of the device mounted to the mounting surface, at each of a plurality of temperatures within a specific operating temperature range, to maintain a connection between the first port of the first integrated circuit and the second port of the second integrated circuit at each of the plurality of temperatures.

Aspects can include one or more of the following features.

The connection between the first port of the first integrated circuit and the second port of the second integrated circuit comprises an optical beam that is emitted from the first port of the first integrated circuit and received into the second port of the second integrated circuit.

The apparatus further comprises one or more optical components mounted to the device carrier and configured to focus, expand, or change a direction of propagation the optical beam.

The connection between the first port of the first integrated circuit and the second port of the second integrated circuit comprises a wirebond connected to the first port of the first integrated circuit and connected to the second port of the second integrated circuit.

The connection between the first port of the first integrated circuit and the second port of the second integrated circuit corresponds to an alignment between the first port of the first integrated circuit and the second port of the second integrated circuit associated with a specific height relative to the first surface.

The circuit interconnection structure comprises a printed circuit board (PCB).

The PCB comprises at least one of a high-density interconnect (HDI) PCB, a high-density buildup (HDBU) substrate, a semi-rigid flex, or a substrate-like PCB (SLP).

The device comprises a temperature control element thermally coupled to the mounting surface of the device carrier and thermally coupled to the second integrated circuit.

The temperature control element comprises a thermo-electric cooler.

The circuit interconnection structure provides one or more electrical connections with one or more respective electrical contacts on the first integrated circuit.

The second portion of the device carrier rigidly connected to the first portion of the device carrier comprises a structure extending horizontally from a substantially vertical wall of the device carrier.

The wall of the device carrier comprises a plurality of materials having different coefficients of thermal expansion.

In another aspect, in general, a method comprises: forming a cavity through an entire thickness between a first surface and a second surface of a circuit interconnection structure; mounting a first integrated circuit on the first surface of the circuit interconnection structure, the first integrated circuit comprising a first port; inserting a first portion of a device carrier within at least a portion of the cavity, and attaching a second portion of the device carrier, rigidly connected to the first portion of the device carrier, to the first surface of the circuit interconnection structure; and positioning a device within the first portion of the device carrier and mounting the device to a mounting surface of the device carrier that is substantially parallel to the first surface of the circuit interconnection structure, the device comprising a second integrated circuit comprising a second port. A total thermal expansion of the device carrier between the second portion of the device carrier and the mounting surface of the device carrier is substantially equal to a total thermal expansion of the device between the second integrated circuit and the portion of the device mounted to the mounting surface, at each of a plurality of temperatures within a specific operating temperature range, to maintain a connection between the first port of the first integrated circuit and the second port of the second integrated circuit at each of the plurality of temperatures.

Aspects can include one or more of the following features.

The connection between the first port of the first integrated circuit and the second port of the second integrated circuit comprises an optical beam that is emitted from the first port of the first integrated circuit and received into the second port of the second integrated circuit.

The connection between the first port of the first integrated circuit and the second port of the second integrated circuit comprises a wirebond connected to the first port of the first integrated circuit and connected to the second port of the second integrated circuit.

The circuit interconnection structure comprises a printed circuit board (PCB).

The PCB comprises at least one of a high-density interconnect (HDI) PCB, a high-density buildup (HDBU) substrate, a semi-rigid flex, or a substrate-like PCB (SLP).

The device comprises a temperature control element thermally coupled to the mounting surface of the device carrier and thermally coupled to the second integrated circuit.

The circuit interconnection structure provides one or more electrical connections with one or more respective electrical contacts on the first integrated circuit.

The second portion of the device carrier rigidly connected to the first portion of the device carrier comprises a structure extending horizontally from a substantially vertical wall of the device carrier.

The wall of the device carrier comprises a plurality of materials having different coefficients of thermal expansion.

Aspects can have one or more of the following advantages.

The alignment-maintaining techniques described herein can enhance thermal stability, leading to correspondingly higher performance. For example, optical performance for optical coupling can be increased by reducing insertion loss, polarization-dependent loss, and optical crosstalk. Additionally, the direct coupling and substantially athermal design may lead to a reduction in costs and technical difficulties compared to other solutions (e.g., an optical fiber to couple the active chip to the photonic chip). Due to the optical coupling efficiency, the alignment-maintaining optical assembly may require less electrical power than other solutions. The alignment-maintaining techniques can also reduce the chance of damage due to thermal drift. For example, for electrical coupling using a short wirebond between ports of different electrical chips, the enhanced thermal stability reduces stress on the wirebond as temperature changes during operation.

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1A is a schematic diagram of an example alignment-maintaining optical assembly comprising a photonic chip optically coupled to an active chip, viewed from the front.

FIG. 1B is a schematic diagram of an example alignment-maintaining optical assembly comprising a photonic chip optically coupled to an active chip, viewed from the side.

FIG. 1C is a schematic diagram of an example alignment-maintaining optical assembly comprising a photonic chip optically coupled to an active chip, viewed from the front.

FIG. 1D is a schematic diagram of an example alignment-maintaining optical assembly comprising a photonic chip optically coupled to an active chip, viewed from the side.

FIG. 1E is a schematic diagram of an example alignment-maintaining optical assembly comprising a photonic chip optically coupled to an active chip, viewed from the front.

FIG. 1F is a schematic diagram of an example alignment-maintaining optical assembly comprising a photonic chip optically coupled to an active chip, viewed from the side.

FIG. 1G is a schematic diagram of an example alignment-maintaining optical assembly comprising a photonic chip electrically coupled to an active chip, viewed from the front.

FIG. 1H is a schematic diagram of an example alignment-maintaining optical assembly comprising a photonic chip electrically coupled to an active chip, viewed from the side.

### DETAILED DESCRIPTION

The direct coupling of optical components to an optical or electro-optical chip that is attached to a circuit interconnection structure can have several challenges. A circuit interconnection structure such as a printed circuit board (PCB) may include materials that have a relatively high susceptibility to thermal expansion and contraction (e.g., a change in thickness that is dependent on temperature). There are various types of circuit interconnection structures that provide conductive pathways connecting contact pads or other structures that are connected to a chip that is mounted to the circuit interconnection structure (e.g., using different types of materials, or having different thicknesses or form factors). For example, there are various types of PCBs, such as high-density interconnect (HDI) PCBs, high-density build up (HDBU) substrates, structures referred to as a semi-rigid flex, and substrate-like PCBs (SLPs). Some potential challenges may be associated with maintaining alignment of an optical beam that provides a free-space optical coupling using an optical assembly that includes a chip mounted on a PCB and a free-space sub-assembly that is not mounted on that PCB (e.g., both the PCB and the free-space sub-assembly may be mounted on a surface of a thermo-electric cooler). For example, one challenge may be maintaining vertical alignment of the optical assembly over a range of different temperatures, or over the lifetime of the optical assembly. In some examples, the stack-up of the various components comprising the structural link between an optical input of the chip and an optical output of the free-space sub-assembly may be sensitive to temperature changes due to thermal expansion of the PCB. The same stack-up may also be sensitive to environmental changes (e.g., humidity and stress), as well as to long term stability due to the nature of the various components linking the optical beam from the optical components to the photonic chip.

For example, optical gain assemblies (e.g., distributed feedback (DFB) lasers, distributed Bragg reflector (DBR) lasers, external cavity diode lasers (ECDL), and semiconductor optical amplifiers (SOA)) linked to optical integrated circuits (e.g., silicon photonic chips and indium phosphide chips) may be sensitive to such environmental changes. Fully integrated assemblies, such as the one described above, may be common for future pluggable modules (e.g., Quad Small Form-factor Pluggable-Double Density (QSFP-DD), Octal Small Formfactor Pluggable (OSFP), and C form-factor pluggable (CFPx)). Optical gain assemblies may require or benefit from cooling in some applications, for instance, coherent modems that employ precise modulation and demodulation techniques and future generation of direct detection (IMDD) that may benefit from reduced variations in the wavelength of the laser.

In some examples, a PCB (or other circuit interconnection structure) may be routed out by mechanical removal, laser ablation, or etched out to form a cavity through an entire thickness of the PCB. A carrier can be used for mounting an optical sub-assembly to the surface of the PCB on which an optically coupled chip is also mounted, as described in more detail below, which is able to mitigate several factors associated with the PCB (e.g., thermo-elastic expansion, water absorption, and aging of organic material) which would otherwise lead to opto-mechanical instability. Furthermore, the carrier can undergo a thermal expansion or contraction which at least partially counteracts the thermal expansion or contraction of the active optical sub-assembly, reducing or eliminating thermal drifts and increasing long term stability in optical alignment. For example, the carrier can be formed from a selected material having a coefficient of thermal expansion (CTE) that is approximately equal to a weighted average coefficient of thermal expansion of elements stacked up from a bottom mounting surface, as described in more detail below. In some example carriers, the shape of the carrier is similar to that of gull wings, thus offering a reference plane for convenient optical coupling and simplified structural bonding. In order to provide more design flexibility, some example carriers may be formed from two or more materials, allowing a wider range of effective CTEs to be achieved by the carrier, which in turn can allow for athermal alignment-maintaining optical assemblies. Incorporation of the carrier can also reduce vertical thermal crosstalk with the PCB. For example, if the vertical sidewalls of the carrier are relatively thin, the thermal conductivity is relatively low, which reduces the magnitude of the heat flow up or down the thin wall.

As shown in the following examples, when the carrier for the active optical sub-assembly is inserted into a cavity and bonded to a chosen side of a PCB assembly (PCBA), the carrier references the chosen side of the PCBA where other optical components (e.g., a photonic chip) are located, such that an appropriate choice of CTEs can enable an athermal design. Such a configuration may provide better optical alignment from the device within the carrier (e.g., a laser source) to the photonic chip on the PCBA across a range of temperatures, and over the lifetime of the assembly, thus improving optical performance along with reduced optical and thermal power requirements. Additionally, such a configuration may be fabricated with a top-down assembly process optimized for mass-production and lower cost alignment (e.g., a simple stack type assembly, optional CTE budget compensation bench, and component carrier can be partially built, tested, and yielded outside the PCBA cavity).

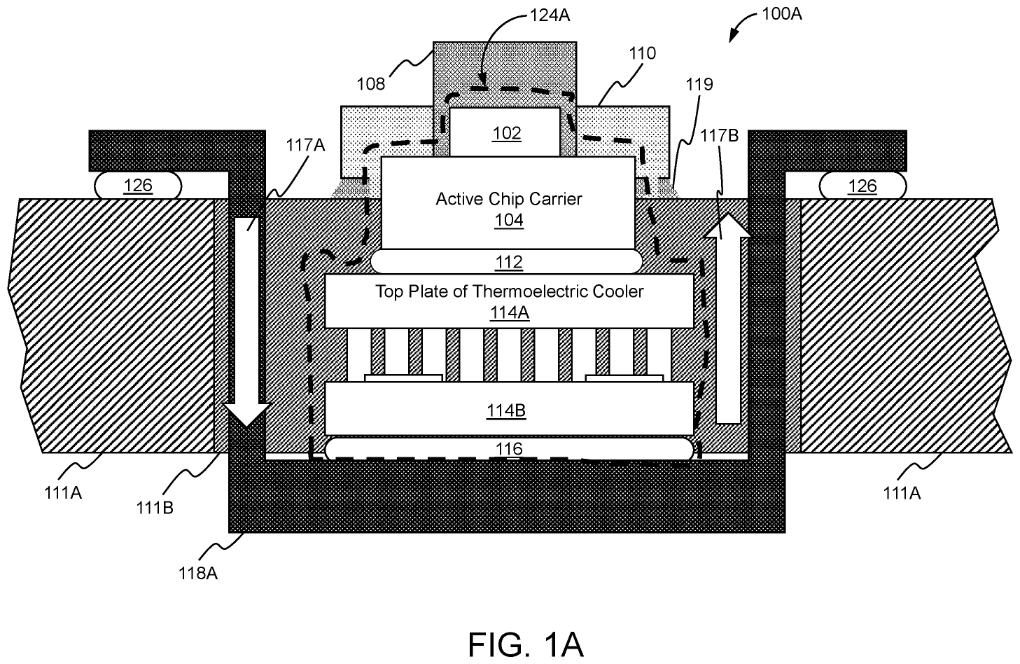

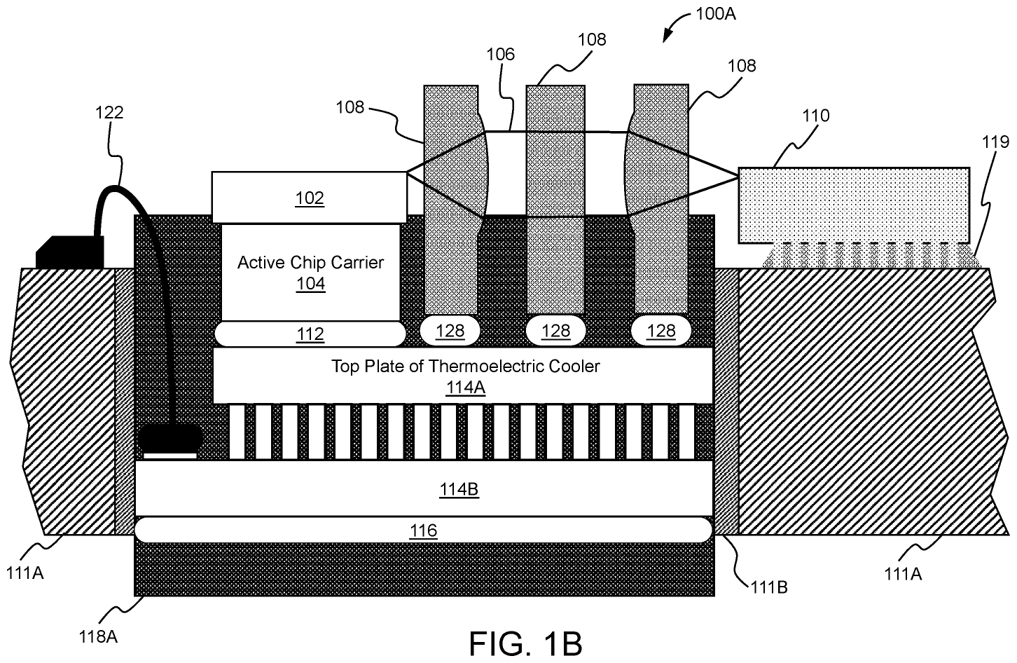

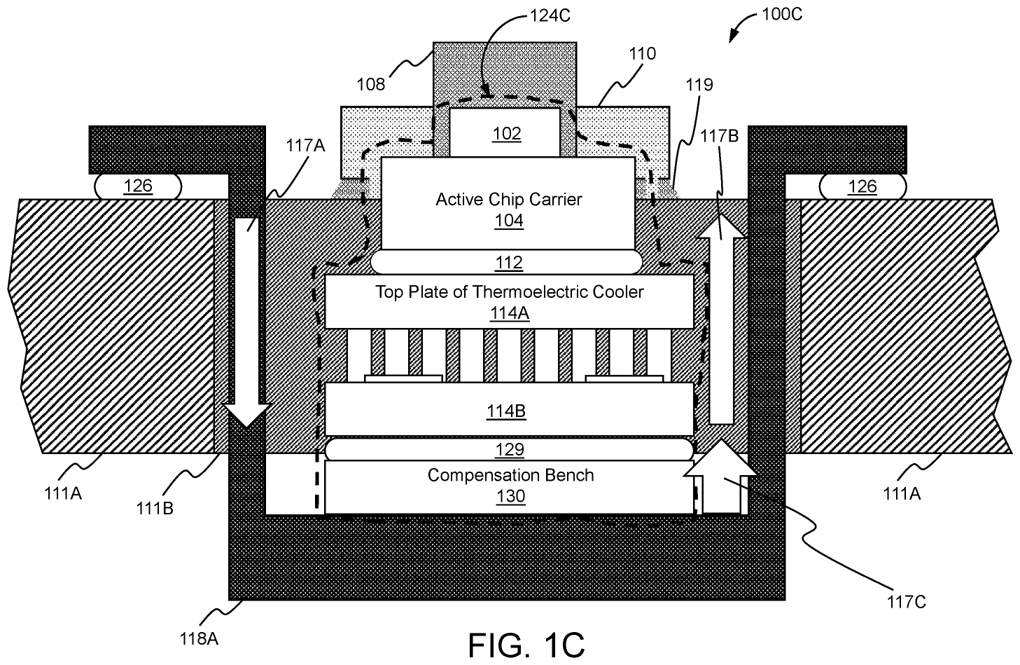

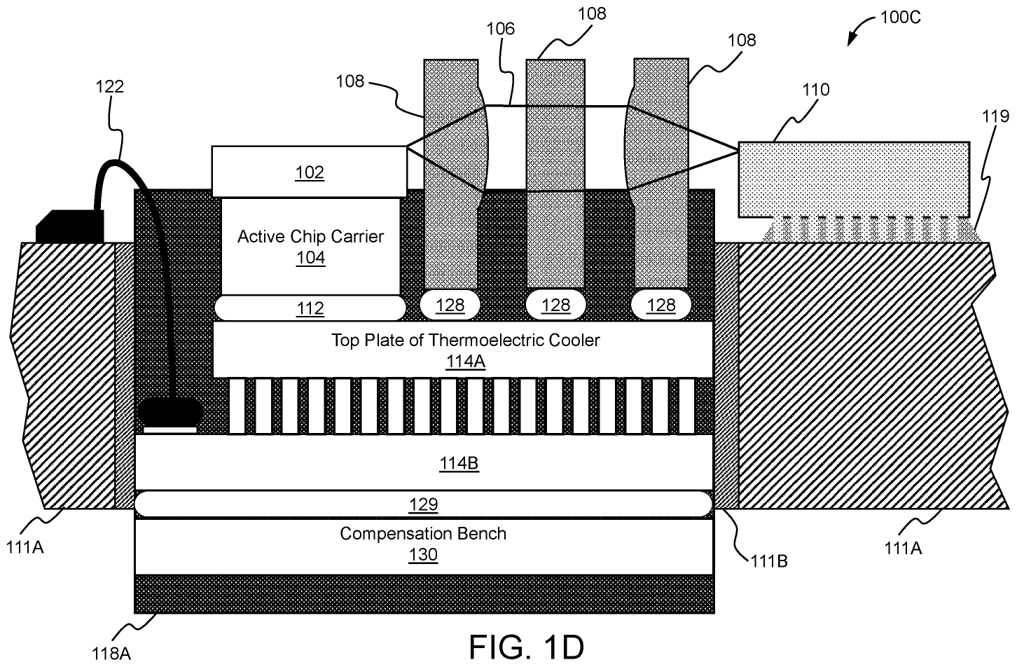

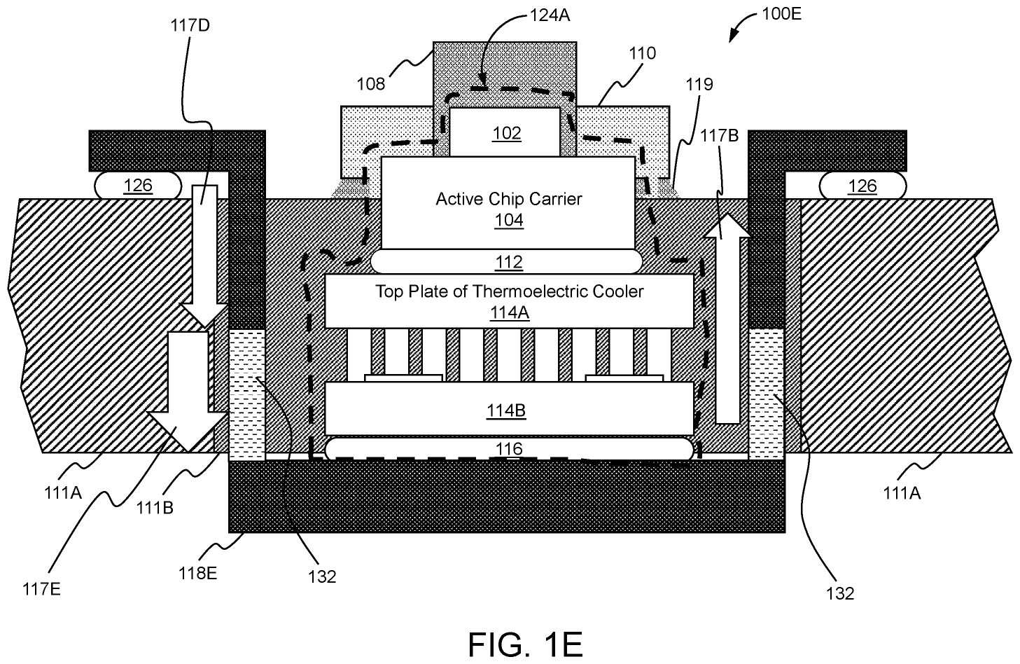

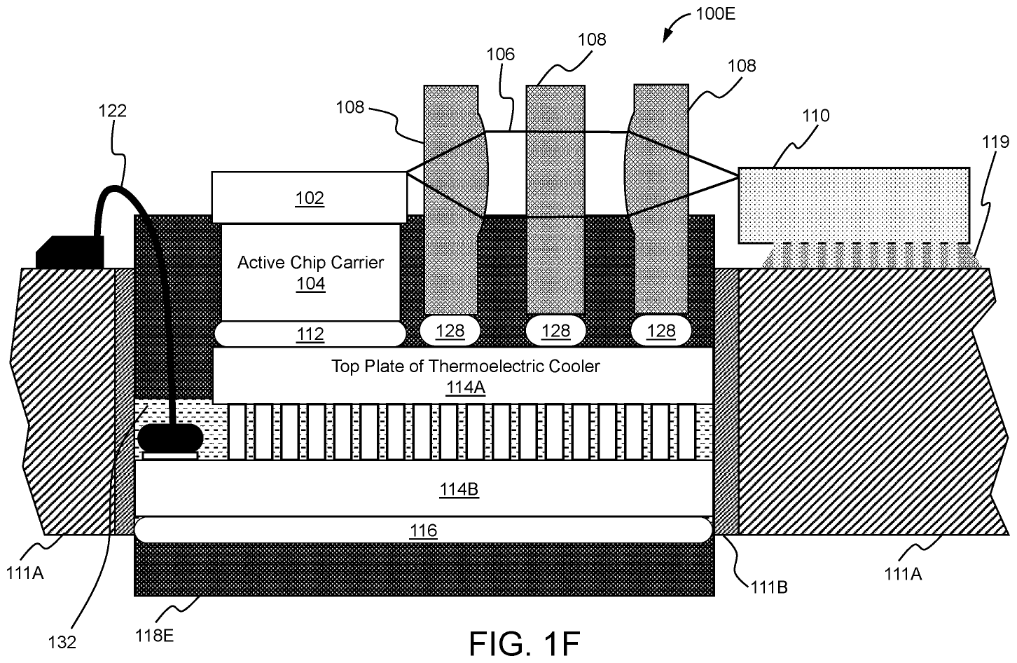

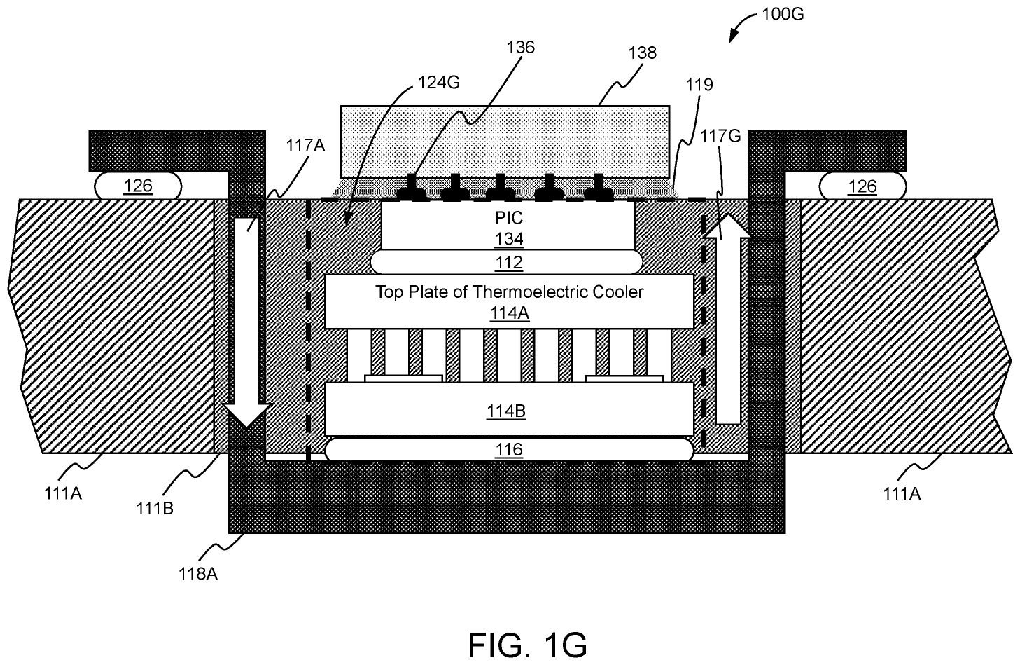

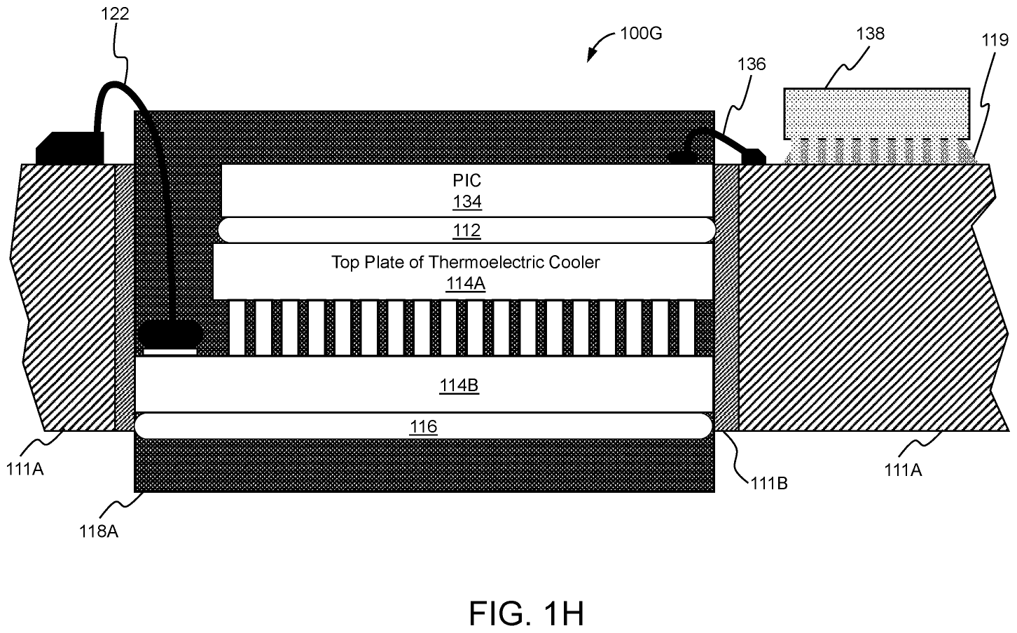

FIG. 1A shows a cross-section of an example alignment-maintaining optical assembly 100A, viewed from the front. An active chip 102, situated on top of an active chip carrier 104, outputs light through optical components 108. For example, the active chip 102 could be a DFB laser, a DBR laser, a gain chip (for an external cavity laser), or a SOA chip. The light is then received by a photonic chip 110 that is attached to the top of a PCB 111A with bonding material 119 (e.g., adhesive, solder, underfill material) filling in the space between the photonic chip 110 and the PCB 111A and around conductive structures (e.g., metal pins, ball grid array, or other metal contacts). Alternatively, instead of a bonding material, an interconnect structure (e.g., C4 bumps, Copper pillars, gold studs, thermocompression bumps) could be used. A cavity is formed through an entire thickness of the PCB 111A between its top and bottom surfaces, and a sidewall 111B of that cavity formed within the PCB 111A is shown to clarify the cross-sectional view. A first thermal interface material 112 is situated between the active chip carrier 104 and a top plate 114A of a thermoelectric cooler. A second thermal interface material 116 is situated between a bottom plate 114B of the thermoelectric cooler and a mounting surface of a carrier 118A. Thermal interface materials 112, 116 can allow for increased thermal coupling between components that are in contact with the thermal interface material. In some examples, the PCB 111A may comprise a stack-up of copper and organic dielectric materials that leads to a substantial effective CTE (e.g., based on a weighted average of the CTEs of the individual materials, where the weights are the respective thicknesses of the materials in the stack-up). The alignment-maintaining optical assembly 100A can reduce the contribution of the PCB 111A in the equation of the CTE stack-up calculations by placing an active optical sub-assembly 124A within the carrier 118A and attaching a laterally extended portion of the carrier 118A directly to the top of the PCB 111A, through the use of a first adhesive 126. Such a configuration effectively removes or reduces the contribution of the entire thickness of the PCB 111A to the thermal expansion relative to chips on the top of the PCB 111A and replaces it with an offsetting difference between a carrier thermal expansion contribution 117A from the carrier 118A (e.g., expanding downward) and an optical sub-assembly thermal expansion contribution 117B (expanding upward). The carrier 118A can have a gull-wing shape to enable contact with the top of the PCB 111A (by the laterally extended wings of the gull-wing shape) while providing a flat bottom surface on which the active optical sub-assembly 124A can be mounted. If the temperature of the alignment-maintaining optical assembly 100A increases, then the carrier 118A will expand and lower the bottom portion of the carrier 118A. However, the height of the active optical sub-assembly 124A will increase, due to thermal expansion associated with an active optical sub-assembly thermal expansion contribution 117B, and thus offset the lowering of the bottom portion of the carrier 118A. The thermal expansion of physical dimensions occurs when temperatures increase, and a similar offsetting effect occurs when temperature decreases and the directions of the contributions 117A and 117B reverse to represent contracting physical dimensions instead of expanding physical dimensions. If the temperature of the alignment-maintaining optical assembly 100A decreases, then the carrier 118A will contract and raise the bottom portion of the carrier 118A. However, the height of the active optical sub-assembly 124A will decrease due to thermal contraction, and thus offset the raising of the bottom portion of the carrier 118A. Thus, optical alignment between the active chip 102 and the photonic chip 110 can be maintained over a relatively large range of temperatures within a specific operating temperature range. For example, in some cases, uncontrolled environment temperatures can range from −40 C up to +85 C for telecommunication applications, but can also reach −50 C to +125 C in specific applications. An athermal design is achieved when the thermal expansion contribution 117A and the thermal expansion contribution 117B are substantially equal, resulting in a substantially constant vertical position of the output port of the active chip 102 with respect to the vertical position of the input port of the photonic chip 110 as temperature changes. Careful selection of the materials of the carrier 118A, such as copper tungsten alloys, can offer both thermal conductivity and low CTE. Larger thermal conductivity of the carrier 118A can assist the thermoelectric cooler in controlling the temperature of the active optical sub-assembly 124A. Furthermore, by placing the active chip 102 on the carrier 118A, the thermal crosstalk between the active chip 102 and the photonic chip 110 is reduced by reducing thermal contact between the two components.

FIG. 1B shows a cross-section of the example alignment-maintaining optical assembly 100A, viewed from the side. The active chip 102, situated on top of the active chip carrier 104, outputs light 106 from an output port (e.g., an optical edge coupler from a waveguide) of the active chip 102 through optical components 108 (e.g., including collimating and focusing lenses). The light 106 is then received into an input port (e.g., an optical edge coupler into a waveguide) of the photonic chip 110 situated on top of the PCB 111A. An electrical connection 122 electrically connects the PCB 111A and the thermoelectric cooler. A second adhesive 128 is situated between the optical components 108 and the top plate 114A of the thermoelectric cooler. The wings of the gull-wing shape of the carrier 118A are not visible in this view, but other implementations of the carrier may have additional laterally extended portions that make contact with the top of the PCB 111A. For example, there may be three or four laterally extended portions instead of the two laterally extended portions of the gull-wing shape, or there may be a U-shape, semi-circular shape, circular shape (like the brim of an inverted top hat), or other arrangement of laterally extended portion(s) rigidly connected to the vertical walls of the lower portion of the carrier and mounted to the top of the PCB 111A.

In some examples, the alignment-maintaining optical assembly can further comprise a compensation bench. For instance, referring again to FIG. 1A, if the distance that the bottom portion of the carrier 118A is lowered or raised via thermal expansion or contraction is larger than the distance that the active optical sub-assembly 124A thermally expands or contracts, a compensation bench can provide extra expansion or contraction so as to maintain optical alignment of the active optical sub-assembly 124A with the photonic chip 110.

FIG. 1C shows a cross-section of an example alignment-maintaining optical assembly 100C, viewed from the front. A third thermal interface material 129 is situated between the bottom plate 114B of the thermoelectric cooler and a compensation bench 130. The compensation bench 130 has compensation bench thermal expansion contribution 117C that can be used to provide compensation that can help maintain alignment of the active optical sub-assembly 124C with the photonic chip 110. For example, the compensation bench 130 can consist essentially of a material that has a predetermined coefficient of thermal expansion and a predetermined thickness that is tuned to provide the desired compensation (e.g., an athermal design). Or, in some implementations, the compensation bench can comprise multiple materials together that have a weighted average coefficient of thermal expansion and total thicknesses to achieve the desired compensation (e.g., an athermal design). The compensation bench 130 can act as an additional tuning knob to further adjust the equation representing the CTE of the vertical stack-up, for instance, by having a higher CTE than the optical elements 108 and the thermoelectric cooler 114 situated on top of it. The alignment-maintaining optical assembly 100C may be made substantially athermal by the use of the carrier 118A, with the compensation bench 130 providing additional athermal design parameters. For substantially athermal designs, temperature changes would have a significantly reduced effect on the vertical alignment of the optical path between the active chip 102 and the photonic chip 110.

FIG. 1D shows a cross-section of the example alignment-maintaining optical assembly 100C, viewed from the side.

FIG. 1E shows a cross-section of an example alignment-maintaining optical assembly 100E, viewed from the front. A bi-material carrier 118E can be used to increase the vertical thermal stability of the alignment-maintaining optical assembly 100E. The bi-material carrier 118E comprises sidewall sections of a second compensation material 132 (e.g., aluminum, Cu, W, CuMo, CuW, AlN, Al2O3, WC, or ceramic material). In some examples, the sidewall of the bi-material carrier 118E comprises two dissimilar materials joined together. The bi-material carrier 118E, with an associated effective CTE, can be used to provide compensation that can help maintain alignment of the active optical sub-assembly 124A with the photonic chip 110. The bi-material carrier 118E can act as an additional tuning knob to further adjust the equation representing the CTE of the vertical stack-up, for instance, by having a higher CTE than the material of the carrier 118A in FIG. 1A. The alignment-maintaining optical assembly 100E may be made substantially athermal by the use of the carrier 118E.

FIG. 1F shows a cross-section of the example alignment-maintaining optical assembly 100E, viewed from the side.

FIG. 1G shows a cross-section of an example alignment-maintaining optical assembly 100G, viewed from the front. A photonic integrated circuit (PIC) 134 is electrically connected to the PCB 111A using relatively short RF wirebonds 136. An integrated circuit 138 (e.g., an application-specific IC (ASIC)) is situated on top of the PCB 111A and may be electrically connected to some or all of the RF wirebonds 136. An active optical sub-assembly 124G undergoes thermal expansion or contraction, with a corresponding active optical sub-assembly thermal expansion contribution 117G. In this example, offsetting with respect to the carrier thermal expansion contribution 117A enables the top of the PIC 134 and the top of the PCB 11A to be physically aligned to each other to reduce any significant mechanical stress on the wirebonds 136 that might otherwise cause potential damage at the contact points of the wirebonds 136 as the stress occurs repeatedly as the temperature cycles during repeated operation (i.e., material fatigue).

FIG. 1H shows a cross-section of the example alignment-maintaining optical assembly 100G, viewed from the side.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An apparatus comprising:
a circuit interconnection structure comprising a first surface and a second surface, with a cavity formed through an entire thickness between the first surface and the second surface;
a first integrated circuit comprising a first port, the first integrated circuit mounted on the first surface of the circuit interconnection structure;
a device carrier comprising a first portion of the device carrier that fits within at least a portion of the cavity, wherein a second portion of the device carrier rigidly connected to the first portion of the device carrier is attached to the first surface of the circuit interconnection structure; and
a device positioned within the first portion of the device carrier and mounted to a mounting surface of the device carrier that is substantially parallel to the first surface of the circuit interconnection structure, the device comprising a second integrated circuit comprising a second port;
wherein a total thermal expansion of the device carrier between the second portion of the device carrier and the mounting surface of the device carrier is substantially equal to a total thermal expansion of the device between the second integrated circuit and the portion of the device mounted to the mounting surface, at each of a plurality of temperatures within a specific operating temperature range, to maintain a connection between the first port of the first integrated circuit and the second port of the second integrated circuit at each of the plurality of temperatures.

2. The apparatus of claim 1, wherein the connection between the first port of the first integrated circuit and the second port of the second integrated circuit comprises an optical beam that is emitted from the first port of the first integrated circuit and received into the second port of the second integrated circuit.

3. The apparatus of claim 2, further comprising one or more optical components mounted to the device carrier and configured to focus, expand, or change a direction of propagation the optical beam.

4. The apparatus of claim 1, wherein the connection between the first port of the first integrated circuit and the second port of the second integrated circuit comprises a wirebond connected to the first port of the first integrated circuit and connected to the second port of the second integrated circuit.

5. The apparatus of claim 1, wherein the connection between the first port of the first integrated circuit and the second port of the second integrated circuit corresponds to an alignment between the first port of the first integrated circuit and the second port of the second integrated circuit associated with a specific height relative to the first surface.

6. The apparatus of claim 1, wherein the circuit interconnection structure comprises a printed circuit board (PCB).

7. The apparatus of claim 6, wherein the PCB comprises at least one of a high-density interconnect (HDI) PCB, a high-density buildup (HDBU) substrate, a semi-rigid flex, or a substrate-like PCB (SLP).

8. The apparatus of claim 1, wherein the device comprises a temperature control element thermally coupled to the mounting surface of the device carrier and thermally coupled to the second integrated circuit.

9. The apparatus of claim 8, wherein the temperature control element comprises a thermo-electric cooler.

10. The apparatus of claim 1, wherein the circuit interconnection structure provides one or more electrical connections with one or more respective electrical contacts on the first integrated circuit.

11. The apparatus of claim 1, wherein the second portion of the device carrier rigidly connected to the first portion of the device carrier comprises a structure extending horizontally from a substantially vertical wall of the device carrier.

12. The apparatus of claim 11, wherein the wall of the device carrier comprises a plurality of materials having different coefficients of thermal expansion.

13. A method comprising:
forming a cavity through an entire thickness between a first surface and a second surface of a circuit interconnection structure;
mounting a first integrated circuit on the first surface of the circuit interconnection structure, the first integrated circuit comprising a first port;
inserting a first portion of a device carrier within at least a portion of the cavity, and attaching a second portion of the device carrier, rigidly connected to the first portion of the device carrier, to the first surface of the circuit interconnection structure; and
positioning a device within the first portion of the device carrier and mounting the device to a mounting surface of the device carrier that is substantially parallel to the first surface of the circuit interconnection structure, the device comprising a second integrated circuit comprising a second port;
wherein a total thermal expansion of the device carrier between the second portion of the device carrier and the mounting surface of the device carrier is substantially equal to a total thermal expansion of the device between the second integrated circuit and the portion of the device mounted to the mounting surface, at each of a plurality of temperatures within a specific operating temperature range, to maintain a connection between the first port of the first integrated circuit and the second port of the second integrated circuit at each of the plurality of temperatures.

14. The method of claim 13, wherein the connection between the first port of the first integrated circuit and the second port of the second integrated circuit comprises an optical beam that is emitted from the first port of the first integrated circuit and received into the second port of the second integrated circuit.

15. The method of claim 13, wherein the connection between the first port of the first integrated circuit and the second port of the second integrated circuit comprises a wirebond connected to the first port of the first integrated circuit and connected to the second port of the second integrated circuit.

16. The method of claim 13, wherein the circuit interconnection structure comprises a printed circuit board (PCB).

17. The method of claim 16, wherein the PCB comprises at least one of a high-density interconnect (HDI) PCB, a high-density buildup (HDBU) substrate, a semi-rigid flex, or a substrate-like PCB (SLP).

18. The method of claim 13, wherein the device comprises a temperature control element thermally coupled to the mounting surface of the device carrier and thermally coupled to the second integrated circuit.

19. The method of claim 13, wherein the circuit interconnection structure provides one or more electrical connections with one or more respective electrical contacts on the first integrated circuit.

20. The method of claim 13, wherein the second portion of the device carrier rigidly connected to the first portion of the device carrier comprises a structure extending horizontally from a substantially vertical wall of the device carrier.

21. The method of claim 20, wherein the wall of the device carrier comprises a plurality of materials having different coefficients of thermal expansion.
